(19) United States
(12) Patent Application Publication
(10) Pub. No.: US 2006/0063105 A1
(43) Pub. Date: Mar. 23, 2006

(54) Negative-working photoimageable bottom antireflective coating

(76) Inventors: Joseph E. Oberlander, Phillipsburg, NJ (US); Ralph R. Dammel, Flemington, NJ (US); Shuji Ding-Lee, Branchburg, NJ (US); Mark O. Neisser, Whitehouse Station, NJ (US); Medhat A. Toukhy, Flemington, NJ (US)

Correspondence Address: AZ ELECTRONIC MATERIALS USA CORP.;ATTENTION: INDUSTRIAL PROPERTY DEPT., 70 MEISTER AVENUE, SOMERVILLE, NJ, 08876, US

(21) Appl. No.: 11/260,761

(22) Filed: Oct. 27, 2005

Related U.S. Application Data
(62) Division of application No. 10/322,239, filed on Dec. 18, 2002, now abandoned.
(60) Provisional application No. 60/347,135, filed on Jan. 9, 2002.

(51) Int. Cl. G03F 7/004; G03F 7/00

(52) U.S. Cl. 430/270.1; 430/322

(57) ABSTRACT

The present invention relates to novel negative-working, photoimageable, and aqueous developable antireflective coating compositions and their use in image processing by forming a thin layer of the novel antireflective coating composition between a reflective substrate and a photoresist coating. The negative bottom photoimageable antireflective coating composition is capable of being developed in an alkaline developer and is coated below a negative photoresist.

This application is a division of application with U.S. Ser. No. 10/322,239, filed Dec. 18, 2002, now pending, which claims the benefit of U.S. Provisional Application No. 60/347,135 filed Jan. 9, 2002.

### FIELD OF THE INVENTION

The present invention relates to novel negative-working, photoimageable, and aqueous developable antireflective coating compositions and their use in image processing by forming a thin layer of the novel antireflective coating composition between a reflective substrate and a photoresist coating. Such compositions are particularly useful in the fabrication of semiconductor devices by photolithographic techniques, especially those requiring exposure with deep ultraviolet radiation.

### BACKGROUND

Photoresist compositions are used in microlithography processes for making miniaturized electronic components such as in the fabrication of computer chips and integrated circuits. Generally, in these processes, a thin coating of a film of a photoresist composition is first applied to a substrate material, such as silicon wafers used for making integrated circuits. The coated substrate is then baked to evaporate any solvent in the photoresist composition and to fix the coating onto the substrate. The baked and coated surface of the substrate is next subjected to an image-wise exposure to radiation.

This radiation exposure causes a chemical transformation in the exposed areas of the coated surface. Visible light, ultraviolet (UV) light, electron beam and X-ray radiant energy are radiation types commonly used today in microlithographic processes. After this image-wise exposure, the coated substrate is treated with a developer solution to dissolve and remove either the radiation-exposed or the unexposed areas of the photoresist.

There are two types of photoresist compositions, negative-working and positive-working. When negative-working photoresist compositions are exposed image-wise to radiation, the areas of the photoresist composition exposed to the radiation become less soluble in a developer solution (e.g. a cross-linking reaction occurs) while the unexposed areas of the photoresist coating remain relatively soluble in such a solution. Thus, treatment of an exposed negative-working photoresist with a developer causes removal of the non-exposed areas of the photoresist coating and the formation of a negative image in the coating, thereby uncovering a desired portion of the underlying substrate surface on which the photoresist composition was deposited. In a positive-working photoresist the developer removes the portions that are exposed.

The trend towards the miniaturization of semiconductor devices has led both to the use of new photoresists that are sensitive to lower and lower wavelengths of radiation, and also to the use of sophisticated multilevel systems to overcome difficulties associated with such miniaturization.

High resolution, chemically amplified, deep ultraviolet (100-300 nm in wavelength) positive and negative tone photoresists are available for patterning images with less than quarter micron geometries. There are currently two major deep ultraviolet (uv) exposure technologies that have provided significant advancement in miniaturization, and these are lasers that emit radiation at 248 nm and 193 nm. Other wavelengths can be used and it is expected that shorter wavelengths, such as 157 nm, will come into use in the future. Examples of such photoresists are given in the following patents and incorporated herein by reference, U.S. Pat. No. 4,491,628, U.S. Pat. No. 5,069,997, U.S. Pat. No. 5,350,660, EP 794,458 and GB 2,320,718. Photoresists for 248 nm have typically been based on substituted polyhydroxystyrene and its copolymers. On the other hand, photoresists for 193 nm exposure require non-aromatic polymers, since aromatics are opaque at this wavelength. Generally, alicyclic hydrocarbons are incorporated into the polymer to replace the etch resistance lost by eliminating the aromatic functionality. Furthermore, at lower wavelengths the reflection from the substrate becomes increasingly detrimental to the lithographic performance of the photoresist. Therefore, at these wavelengths antireflective coatings become critical.

The use of highly absorbing antireflective coatings in photolithography is a simple approach to diminish the problems that result from back reflection of light from highly reflective substrates. Two major disadvantages of back reflectivity are thin film interference effects and reflective notching. Thin film interference causes standing waves, which changes critical line width dimensions caused by variations in the total light intensity in the photoresist film as the thickness of the photoresist changes, and changes in light intensity in the film when the thickness of underlying layers of material are changed. Reflective notching becomes severe as the photoresist is patterned over substrates containing topographical features, which scatter light through the photoresist film, leading to line width variations, and in the extreme case, forming regions with complete photoresist loss (for positive resist) or with bridging between features (negative resist).

The use of bottom antireflective coating provides the best solution for the elimination of reflectivity. The bottom antireflective coating is applied on the substrate and then a layer of photoresist is applied on top of the antireflective coating. The photoresist is exposed imagewise and developed. The antireflective coating in the open area is then typically etched and the photoresist pattern is thus transferred to the substrate. Most antireflective coatings known in the prior art are designed to be dry etched. The etch rate of the antireflective film needs be relatively high in comparison to the photoresist so that the antireflective film is etched without excessive loss of the resist film during the etch process. There are two known types of antireflective coatings, inorganic coatings and organic coatings. However, both of these types of coatings have so far been designed for removal by dry etching.

Inorganic type of coatings include such films as TiN, TiON, TiW and spin-on organic polymer in the range of 30 nm, and are discussed in the following papers: C. Nolscher et al., Proc SPIE vol. 1086, p242 (1989); K. Bather, H. Schreiber, Thin solid films, 200, 93, (1991); G. Czech et al., Microelectronic Engineering, 21, p.51 (1993). Inorganic bottom antireflective coatings require precise control of the film thickness, uniformity of film, special deposition equipment, complex adhesion promotion techniques prior to resist coating, a separate dry etching pattern transfer step, and dry etching for removal. Another very important aspect of dry etching is that the harsh etch conditions can cause damage to the substrate.

Organic bottom antireflective coatings are more preferred and have been formulated by adding dyes to a polymer coating solution or by incorporating the dye chromophore into the polymer structure, but these too need to be dry etched down to the substrate. Polymeric organic antireflective coatings are known in the art as described in EP 583,205, and incorporated herein by reference. It is believed that such antireflective polymers are very aromatic in nature and thus have too low a dry etch rate, especially relative to the new type of non-aromatic photoresists used for 193 nm and 157 nm exposure, and are therefore undesirable for imaging and etching. In addition, photoresist patterns may be damaged or may not be transferred exactly to the substrate if the dry etch rate of the antireflective coating is similar to or less than the etch rate of the photoresist coated on top of the antireflective coating. The etching conditions for removing the organic coatings can also damage the substrate. Thus, there is a need for organic bottom antireflective coatings that do not need to be dry etched especially for compound semiconductor type substrates, which are sensitive to etch damage.

The novel approach of the present application is to use an absorbing photoimageable negative working bottom antireflective coating that can be developed by an aqueous alkaline solution, rather than be removed by dry etching. Aqueous removal of the bottom antireflective coating eliminates the etch rate requirement of the coating, reduces the cost intensive dry etching processing steps and also prevents damage to the substrate caused by dry etching. The bottom antireflective coating compositions of the present invention contain a photoactive compound, a crosslinking compound and a polymer, which on exposure to light of the same wavelength as that used to expose the top negative photoresist, becomes imageable in the same developer as that used to develop the photoresist. In another embodiment the antireflective coating composition comprises a photoactive compound and a polymer that changes polarity or functionality such that its solubility in an aqueous alkaline solution is changed from soluble to insoluble after exposure. This process greatly simplifies the lithographic process by eliminating a large number of processing steps. Since the antireflective coating is photosensitive, the extent of removal of the antireflective coating is defined by the latent optical image, which allows a good delineation of the remaining photoresist image in the antireflective coating.

The antireflective composition disclosed in EP 542 008, is based on highly aromatic polymers, such as novolaks, polyvinyl phenols, copolymers of polyvinyl phenol and styrene or alphamethyl styrene, etc. Furthermore, this antireflective coating in not photoimageable and must be dry etched. Planarizing coatings that can optionally contain absorbing components are known and have been used to planarize topographical features and also prevent reflections. Planarizing layers are fairly thick and are of the order of 1 or 2 microns. Such layers are described in GB 2135793, 4,557,797 and U.S. Pat. No. 4,521,274. However these layers must be either dry etched or removed with an organic solvent, such as methyl isobutyl ketone. In the semiconductor industry removal of coatings by aqueous solutions is greatly preferred over organic solvents.

Bilevel photoresists are known, as discussed in U.S. Pat. No. 4,863,827, but require exposure of two different wavelengths for the top and bottom photoresists, which complicates the processing of the lithography.

There are many patents that disclose antireflective coating compositions but these coatings are all completely cured to be insoluble in an aqueous developer solution and must be removed by dry etching. U.S. Pat. No. 5,939,236 describes an antireflective coating containing a polymer, an acid or thermal acid generator, and a photoacid generator. However this film is completely crosslinked to make it insoluble in an alkaline aqueous developer solution. The film is removed by a plasma gas etch.

Examples of other antireflective coating patents are U.S. Pat. Nos. 5,886,102, 6,080,530, and U.S. Pat. No. 6,251,562.

U.S. Pat. No. 4,910,122 discloses an aqueous developable antireflective coating, however the degree of solubility of the total film is controlled by the bake conditions.

This antireflective coating is not photoimageable, and therefore, there are no clearly defined soluble and insoluble regions in the film. The dissolution of the antireflective coating is controlled by bake conditions and thus the antireflective coating is very sensitive to the developer normality and developing time. High normality developer and/or long develop times can cause excessive removal of the antireflective coating. The resolution of this coating is limited by undercut and photoresist lift off.

Another process for imaging photoresists using antireflective coatings is disclosed in U.S. Pat. No. 5,635,333, however, the antireflective coating is not developed at the same time as the photoresist.

U.S. Pat. No. 5,882,996 describes a method of patterning dual damascene interconnections where a developer soluble antireflective coating interstitial layer is used. The antireflective coating is formed between two photoresist layers and has a preferred thickness of 300-700 angstroms, refractive index of 1.4-2.0 and is water soluble. The antireflective coating is not photoimageable and there is no description of the chemistry of the antireflective coating.

An acid sensitive antireflective coating is disclosed in U.S. Pat. No. 6,110,653, where the antireflective coating is crosslinked by a heating step and is subsequently rendered water soluble in the presence of an acid. The antireflective coating described contains a water soluble resin and a crosslinker, but other components, such as dyes, photoacid generators or amine base may be added. In this invention the water soluble resin is crosslinked before exposure, and if the composition additionally contains a photoacid generator, then the resin is uncrosslinked prior to development.

The novel antireflective composition of the present invention relates to a photoimageable, aqueous developable, negative-working antireflective coating that is imaged with the same wavelength of light as is used to expose the negative photoresist, and thus is imagewise exposed in a single process step. It is further heated, and then developed using the same developer and at the same time as the photoresist. The combination of single exposure step and single development step greatly simplifies the lithographic process. Furthermore, an aqueous developable antireflective coating is highly desirable for imaging with photoresists that do not contain aromatic functionalities, such as those used for 193 nm and 157 nm exposure. The novel composition enables a good image transfer from the photoresist to the substrate, and also has good absorption characteristics to prevent reflective notching and line width variations or standing waves in the photoresist. Furthermore, the novel antireflective coating can be designed, by using the appropriate photosensitivity, to function as an antireflective coating at any imaging wavelength. Additionally, substantially no intermixing is present between the antireflective coating and the photoresist film. The antireflective coatings also have good solution stability and form thin films with good coating quality, the latter being particularly advantageous for lithography. When the antireflective coating is used with a photoresist in the imaging process, clean images are obtained, without causing damage to the substrate.

### SUMMARY OF THE INVENTION

The present invention relates to a negative absorbing bottom photoimageable antireflective coating composition which is capable of being developed in an alkaline developer and which is coated below a negative photoresist, where the antireflective coating composition comprises a photoacid generator, a crosslinking agent and an alkali soluble polymer. The invention further relates to a process for using such a composition.

The present invention also relates to a negative bottom photoimageable antireflective coating composition which is capable of being developed in an alkaline developer and which is coated below a negative photoresist, where the antireflective coating composition comprises a crosslinking agent and an alkali soluble polymer. The invention further relates to a process for using such a composition.

The present invention also relates to a negative bottom photoimageable antireflective coating composition which is capable of being developed in an aqueous alkaline developer and which is coated below a negative photoresist, where the antireflective coating composition comprises a photoacid generator and an aqueous alkali soluble polymer that rearranges upon exposure to become insoluble in an aqueous alkaline developer. The invention further relates to a process for using such a composition.

The present invention also relates to a negative bottom photoimageable antireflective coating composition which is capable of being developed in an aqueous alkaline developer and which is coated below a negative photoresist, where the antireflective coating composition comprises an aqueous alkali soluble polymer that rearranges upon exposure to become insoluble in an aqueous alkaline developer. The invention further relates to a process for using such a composition.

The invention also relates to a process for forming a negative image comprising;
a) providing a coating of a negative bottom photoimageable and alkali developable antireflective coating composition on a substrate;
b) providing a coating of a top photoresist layer;
c) imagewise exposing the top and bottom layer to actinic radiation of same wavelength;
d) postexposure baking the substrate; and,
e) developing the top and bottom layer with an aqueous alkaline solution.

### DESCRIPTION OF THE INVENTION

The present invention relates to a novel absorbing photoimageable and aqueous developable negative-working antireflective coating composition comprising a photoacid generator, a crosslinking agent and an alkali soluble polymer. The present invention also relates to a novel process for imaging such a novel composition. The absorption of the antireflective composition may be as an absorbing chromophore in the polymer or as an additive dye. The invention also relates to a process for imaging a photoimageable antireflective coating composition. The invention also relates to the antireflective coating composition comprising a photoactive compound and a polymer that changes polarity or functionality such that its solubility in aqueous base is changed from soluble to insoluble after exposure.

The antireflective coating composition of the invention is coated on a substrate and below a negative photoresist, in order to prevent reflections in the photoresist from the substrate. This antireflective coating is photoimageable with the same wavelength of light as the top photoresist, and is also developable with the same aqueous alkaline developing solution as that used to typically develop the photoresist. The novel antireflective coating composition comprises an alkali soluble polymer, a crosslinking agent and a photoacid generator, or a photoactive compound and a polymer that changes polarity or functionality such that its solubility in aqueous base is changed from soluble to insoluble after exposure, and is coated on a reflective substrate and baked to remove the solvent of the coating solution. In order to prevent, or minimize, the extent of intermixing between the layers, the components of the antireflective coating are such that they are substantially insoluble in the solvent of the photoresist that is coated on top of the antireflective coating. A negative photoresist is then coated on top of the antireflective coating and baked to remove the photoresist solvent. The coating thickness of the photoresist is generally greater than the underlying antireflective coating. Prior to exposure both the photoresist and the antireflective coating are soluble in the aqueous alkaline developing solution of the photoresist. The bilevel system is then imagewise exposed to radiation in one single step, where an acid is then generated in both the top photoresist and the bottom antireflective coating. In a subsequent bake step the acid causes a reaction between the crosslinking agent and the alkali soluble polymer in the antireflective coating, thus making the polymer in the exposed regions insoluble in the developing solution. A subsequent developing step then dissolves the unexposed regions of both the negative photoresist and the antireflective coating, leaving the substrate clear for further processing.

The novel antireflective coating composition that is useful for the novel process of this invention comprises a photoacid generator, a crosslinking agent and a polymer. In the first embodiment of the invention the antireflective coating comprises a photoacid generator, a crosslinking agent and an alkali soluble polymer comprising at least one unit with an absorbing chromophore. In the second embodiment of the invention the antireflective coating comprises photoacid generator, a crosslinking agent, a dye and an alkali soluble polymer. Thus the absorbing chromophore may be present within the polymer or as an additive in the composition. In a third embodiment the antireflective coating composition comprises a crosslinking agent and an alkali soluble polymer, and the absorbing chromophore is either incorporated into the polymer or added as a dye. In this case the crosslinking in the antireflective coating is caused by the diffusion of the photogenerated acid from the top negative photoresist into the antireflective coating after the exposure step and during the baking step. In a fourth embodiment, the antireflective coating composition consists of a photoactive compound and a polymer that changes polarity or functionality in the presence of the photolyzed photoactive compound such that its solubility in aqueous base is changed from soluble to insoluble after exposure. The absorbance can be intrinsic to the polymer or due to an added dye. In a fifth embodiment, the antireflective coating composition consists of a polymer that changes polarity or functionality in the presence of the acid compound such that its solubility in aqueous base is changed from soluble to insoluble after exposure. The absorbance can be intrinsic to the polymer or due to an added dye. In this case the change in polarity and functionality in the antireflective coating is caused by the diffusion of the photogenerated acid from the top negative photoresist into the antireflective coating after the exposure step and during the baking step.

The photoacid generator in the antireflective coating and the photoacid generator in the photoresist are sensitive to the same wavelength of light, thus the same exposure wavelength of light can cause an acid to be formed in both layers. The photoacid generator of the antireflective coating chosen depends on the photoresist to be used. As an example, for a photoresist that is developed for 193 nm exposure, the photoacid generator of the antireflective coating absorbs at 193 nm; and examples of such photoacid generators are onium salts and sulfonate esters of hyroxyimides, specifically diphenyl iodonium salts, triphenyl sulfonium salts, dialkyl iodonium salts and trialkylsulfonium salts. Photoacid generators for antireflective coatings that are designed for use with photoresists for 248 nm exposure can be onium salts, such as diphenyl iodonium salts, triphenyl sulfonium salts and sulfonate esters of hydroxyimides. For exposure at 365 nm the photoacid generator can be diazonaphthoquinones, especially 2,1,4 diazonaphthoquinones that are capable of producing strong acids that can react with the acid labile groups of the polymer. Oxime sulfonates, substituted or unsubstituted naphthalimidyl triflates or sulfonates are also known as photoacid generators. Any photoacid generator that absorbs light at the same wavelength as the top photoresist may be used. Photoacid generators known in the art may be used, such as those disclosed in the U.S. Pat. No. 5,731,386, U.S. Pat. No. 5,880,169, U.S. Pat. No. 5,939,236, U.S. Pat. No. 5,354,643, U.S. Pat. No. 5,716,756, DE 3,930,086, DE 3,930,087, German Patent Application P 4,112,967.9, F. M. Houlihan et al., J. Photopolym. Sci. Techn., 3:259 (1990); T. Yamaoka et al., J. Photopolym. Sci. Techn., 3:275 (1990)), L. Schlegel et al., J. Photopolym. Sci. Techn., 3:281 (1990) or M. Shirai et al., J. Photopolym. Sci. Techn., 3:301 (1990), and incorporated herein by reference. The acid generated in the exposed regions of the antireflective coating reacts with the polymer containing the acid labile group to make it soluble in the developer, and hence produce a positive image on the substrate without a dry etching step and incorporated herein by reference. The acid generated in the exposed regions of the antireflective coating reacts with the polymer containing the acid labile group to make it soluble in the developer, and hence produce a positive image on the substrate without a dry etching step.

A variety of crosslinking agents can be used in the composition of the present invention. Any suitable crosslinking agent that can crosslink the polymer in the presence of an acid may be used. Any of the crosslinking agents known in the art may be used, such as those disclosed in U.S. Pat. No. 5,886,102 and U.S. Pat. No. 5,919,599, and which are incorporated herein by reference. Examples of such crosslinking agents are melamines, methylols, glycolurils, hydroxy alkyl amides, epoxy and epoxy amine resins, blocked isocyanates, and divinyl monomers. Melamines like hexamethoxymethyl melamine and hexabutoxymethylmelamine; glycolurils like tetrakis(methoxymethyl)glycoluril and tetrabutoxyglycoluril; and aromatic methylols, like 2,6 bishydroxymethyl p-cresol are preferred. Other crosslinkers are tertiary diols such as 2,5-dimethyl-2,5-hexanediol, 2,4-dimethyl-2,4-pentanediol, pinacol, 1-methylcyclohexanol, tetramethyl-1,3-benzenedimethanol, and tetramethyl-1,4-benzenedimethanol, and polyphenols, such as tetramethyl-1,3-benzenedimethanol.

The polymer of the novel invention comprises at least one unit which makes the polymer soluble in an aqueous alkaline developing solution. One function of the polymer is to provide a good coating quality and another is to enable the antireflective coating to change solubility from exposure to development. Examples of monomers that impart alkali solubility are acrylic acid, methacrylic acid, vinyl alcohol, maleimide, thiophene, N-hydroxymethyl acrylamide, N-vinyl pyrrolidinone. More examples are vinyl compounds of substituted and unsubstituted sulfophenyl and its tetraalkylammonium salts, substituted and unsubstituted hydroxycarbonylphenyl and its tetraalkylammonium salts such as 3-(4-sulfophenyl)azoacetoacetoxy ethyl methacrylate and its tetraalkylammonium salt, 3-(4-hydroxycarbonylphenyl)azoacetoacetoxy ethyl methacrylate and its tetraalkylammonium salt, N-(3-hydroxy-4-sulfophenylazo)phenyl methacrylamide and its tetraalkylammonium salt, N-(3-hydroxy-4-hydroxycarbonylphenylazo)phenyl methacrylamide and its tetraalkylammonium salt, where alkyl is H and C₁-C₄ groups.

Examples of monomers that can be cross linked are monomers with hydroxyl functionality such as hydroxyethyl methacrylate or those described in S. C. Fu et al. Proc. SPIE, Vol 4345, (2001) p. b751, monomers with acetal functionality, such as those described in UK Patent application 2,354,763 A and U.S. Pat. No. 6,322,948 B1, monomers with imide functionality, and monomers with carboxylic acid or anhydride functionality, such as are described in Naito et al. Proc. SPIE, vol. 3333 (1998), p. 503.

Preferably the monomers are acrylic acid, methacrylic acid, vinyl alcohol, maleic anhydride, maleic acid, maleimide, N-methyl maleimide, N-hydroxymethyl acrylamide, N-vinyl pyrrolidinone. 3-(4-sulfophenyl)azoacetoacetoxy ethyl methacrylate and its tetrahydroammonium salt, 3-(4-hydroxycarbonylphenyl)azoacetoacetoxy ethyl methacrylate and its tetrahydroammonium salt, N-(3-hydroxy-4-hydroxycarbonylphenylazo)phenyl methacrylamide and its tetrahydroammonium salt. More preferred are groups acrylic acid, methacrylic acid, vinyl alcohol, maleic anhydride, maleic acid, maleimide, N-methyl maleimide, N-hydroxymethyl acrylamide, N-vinyl pyrrolidinone. tetrahydroammonium salt of 3-(4-sulfophenyl)azoacetoacetoxy ethyl methacrylate. The alkali soluble monomers may be polymerized to give homopolymers or with other monomers as required. The other monomers may be alkali insoluble, dyes, etc.

In one particular embodiment the polymer of the antireflective coating contains at least one unit which is alkali soluble and at least one unit with an absorbing chromophore. Examples of an absorbing chromophore are hydrocarbon aromatic moieties and heterocyclic aromatic moieties with from one to four separate or fused rings, where there are 3 to 10 atoms in each ring. Examples of monomers with absorbing chromophores that can be polymerized with the monomers containing the acid labile groups are vinyl compounds containing substituted and unsubstituted phenyl, substituted and unsubstituted anthracyl, substituted and unsubstituted phenanthryl, substituted and unsubstituted naphthyl, substituted and unsubstituted heterocyclic rings containing heteroatoms such as oxygen, nitrogen, sulfur, or combinations thereof, such as pyrrolidinyl, pyranyl, piperidinyl, acridinyl, quinolinyl. Other chromophores are described in U.S. Pat. No. 6,114,085, U.S. Pat. No. 5,652,297, U.S. Pat. No. 5,981,145, U.S. Pat. No. 5,939,236, U.S. Pat. No. 5,935,760 and U.S. Pat. No. 6,187,506, which may also be used, and are incorporated herein by reference. The preferred chromophores are vinyl compounds of substituted and unsubstituted phenyl, substituted and unsubstituted anthracyl, and substituted and unsubstituted naphthyl; and more preferred monomers are styrene, hydroxystyrene, acetoxystyrene, vinyl benzoate, vinyl 4-tert-butylbenzoate, ethylene glycol phenyl ether acrylate, phenoxypropyl acrylate, 2-(4-benzoyl-3-hydroxyphenoxy)ethyl acrylate, 2-hydroxy-3-phenoxypropyl acrylate, phenyl methacrylate, benzyl methacrylate, 9-anthracenylmethyl methacrylate, 9-vinylanthracene, 2-vinyinaphthalene, N-vinylphthalimide, N-(3-hydroxy)phenyl methacrylamide, N-(3-hydroxy-4-nitrophenylazo)phenyl methacrylamide, N-(3-hydroxyl-4-ethoxycarbonylphenylazo)phenyl methacrylamide, N-(2,4-dinitrophenylaminophenyl)maleimide, 3-(4-acetoaminophenyl)azo-4-hydroxystyrene, 3-(4-ethoxycarbonylphenyl)azo-acetoacetoxy ethyl methacrylate, 3-(4-hydroxyphenyl)azo-acetoacetoxy ethyl methacrylate, 3-(4-nitrophenyl)azoacetoacetoxy ethyl methacrylate, 3-(4-methoxycarbonylphenyl)azoacetoacetoxy ethyl methacrylate.

Other than the unit containing the alkali soluble group and the absorbing chromphore, the polymer may contain other nonabsorbing, alkali insoluble monomeric units, such units may provide other desirable properties. Examples of the third monomer are —CR₁R₂—CR₃R₄—, where R₁ to R₄ are independently H, (C₁-C₁₀) alkyl, (C₁-C₁₀) alkoxy, nitro, halide, cyano, alkylaryl, alkenyl, dicyanovinyl, SO₂CF₃, COOZ, SO₃Z, COZ, OZ, NZ₂, SZ, SO₂Z, NHCOZ, SO₂NZ₂, where Z is (C₁-C₁₀) alkyl, hydroxy (C₁-C₁₀) alkyl, (C₁-C₁₀) alkylOCOCH₂COCH₃, or R₂ and R₄ combine to form a cyclic group such as anhydride, pyridine, or pyrollidone.

Thus a polymer may be synthesized by polymerizing monomers that contain an alkali soluble group with monomers that contain an absorbing chromophore. Alternatively, the alkali soluble polymer may be reacted with compounds that provide the absorbing chromophore. The mole % of the alkali soluble unit in the final polymer can range from 5 to 95, preferably 30 to70, more preferably 40 to 60, and the mole % of the absorbing chromophore unit in the final polymer can range from 5 to 95, preferably 30 to 70, more preferably 40 to 60. It is also within the scope of this invention that the alkali soluble group is attached to the absorbing chromphore, or vice versa, for example, vinyl compounds of substituted and unsubstituted sulfophenyl and its tetraalkylammonium salts, substituted and unsubstituted hydroxycarbonylphenyl and its tetraalkylammonium salts such as 3-(4-sulfophenyl)azoacetoacetoxy ethyl methacrylate and its tetraalkylammonium salt, 3-(4-hydroxycarbonylphenyl)azoacetoacetoxy ethyl methacrylate and its tetraalkylammonium salt, N-(3-hydroxy-4-sulfophenylazo)phenyl methacrylamide and its tetraalkylammonium salt, N-(3-hydroxy-4-hydroxycarbonylphenylazo)phenyl methacrylamide and its tetraalkylammonium salt, where alkyl is H and C₁-C₄ groups.

Examples of polymers that contain both the alkali soluble group and the absorbing chromophore and are suitable for this invention are copolymers of at least one of N methyl maleimide, N alkynol maleimide, acrylic acid, methacrylic acid, vinyl alcohol, maleic anhydride, maleic acid, maleimide, N-hydroxymethyl acrylamide, N-vinyl pyrrolidinone. 3-(4-sulfophenyl)azoacetoacetoxy ethyl methacrylate and its tetrahydroammonium salt, 3-(4-hydroxycarbonylphenyl)azoacetoacetoxy ethyl methacrylate and its tetrahydroammonium salt, N-(3-hydroxy-4-hydroxycarbonylphenylazo)phenyl methacrylamide and its tetrahydroammonium salt, with at least one of styrene, hydroxystyrene, acetoxystyrene, vinyl benzoate, vinyl 4-tert-butylbenzoate, ethylene glycol phenyl ether acrylate, phenoxypropyl acrylate, 2-(4-benzoyl-3-hydroxyphenoxy)ethyl acrylate, 2-hydroxy-3-phenoxypropyl acrylate, phenyl methacrylate, benzyl methacrylate, 9-anthcenylmethyl methacrylate, 9-vinylanthracene, 2-vinylnaphthalene, N-vinylphthalimide, N-(3-hydroxy)phenyl methacrylamide, N-(3-hydroxy4-nitrophenylazo)phenyl methacrylamide, N-(3-hydroxyl-4-ethoxycarbonylphenylazo)phenyl methacrylamide, N-(2,4-dinitrophenylaminophenyl)maleimide, 3-(4-acetoaminophenyl)azo-4-hydroxystyrene, 3-(4-ethoxycarbonylphenyl)azo-acetoacetoxy ethyl methacrylate, 3-(4-hydroxyphenyl)azo-acetoacetoxy ethyl methacrylate, 3-(4-nitrophenyl)azoacetoacetoxy ethyl methacrylate, 3-(4-methoxycarbonylphenyl)azoacetoacetoxy ethyl methacrylate.

Examples of antireflective coating compositions comprise 1) a copolymer of at least one of acetoxystyrene, hydroxystyrene, styrene, benzyl methacrylate, phenyl methacrylate, 9-anthracenylmethyl methacrylate, 9-vinylanthracene, 3-(4-methoxycarbonylphenyl)azoacetoacetoxy ethyl methacrylate, 3-(4-hodroxycarbonylphenyl)azoacetoacetoxy ethyl methacrylate or mixtures thereof, with at least one of maleimide, N-methyl maleimide, N-methylol maleimide, vinyl alcohol, allyl alcohol, acrylic acid, methacrylic acid, maleic anhydride, thiophene, methacrylate ester of beta-hydroxy-gamma-butyrolactone, 2-methyl-2-adamantyl methacrylate, 3-hydroxy-1-adamantyl methacrylate, methcrylate ester of mevalonic lactone, or mixtures thereof 2) a crosslinker such as tetrakis(methoxymethyl)glycoluril and hexaalkoxymethylmelamine, 3) a photoacid generator such as triphenylsulfonium nonaflate, diphenyliodonium nonaflate, 2,1,4-diazonaphthoquinones, 4) optionally, some additives such as amine and surfactant, and 5) solvent or mixtures of solvents such as propylene glycol monomethyl ether acetate, propylene glycol monomethyl ether, and ethyl lactate.

One of the preferred embodiments is a polymer of hydroxystyrene, styrene and N-methyl maleimide, where preferably the maleimide ranges from 30 to 70 mole %, styrene ranges from 5 to 50 mole % and hydroxystyrene ranges from 5 to 50 mole %, more preferably maleimide ranges from 40 to 60 mole %, styrene ranges from 10 to 40 mole % and hydroxystyrene ranges from 10 to 40 mole %, and even more preferably styrene and hydroxystyrene each range from 20 to 30 mole %.

The second embodiment of the present invention relates to an antireflective coating composition comprising a polymer with at least one unit which makes the polymer soluble in an aqueous alkaline developing solution, a dye, a crosslinking agent and a photoacid generator. In this particular invention the absorption necessary for the antireflective coating is provided not by the unit in the polymer, but by the incorporation of an additive that absorbs at the exposure wavelength. This dye may be monomeric, polymeric or mixtures of both. Examples of such dyes are substituted and unsubstituted phenyl, substituted and unsubstituted anthracyl, substituted and unsubstituted phenanthryl, substituted and unsubstituted naphthyl, substituted and unsubstituted heterocyclic rings containing heteroatoms such as oxygen, nitrogen, sulfur, or combinations thereof, such as pyrrolidinyl, pyranyl, piperidinyl, acridinyl, quinolinyl. Absorbing polymeric dyes that may be used are polymers of the absorbing moieties listed above, where the polymer backbone may be polyesters, polyimides, polysulfones and polycarbonates. Some of the preferred dyes are copolymer of hydroxystyrene and methyl methacrylate, such as disclosed in U.S. Pat. No. 6,114,085, and azo polymeric dyes, such as disclosed in U.S. Pat. No. 5,652,297, U.S. Pat. No. 5,763,135, U.S. Pat. No. 5,981,145, U.S. Pat. No. 5,939,236, U.S. Pat. No. 5,935,760, and U.S. Pat. No. 6,187,506, all of which are incorporated herein by reference.

Preferred are monomers or homo- or co-polymers of as triphenylphenol, 2-hydroxyfluorene, 9-anthracenemethanol, 2-methylphenanthrene, 2-naphthaleneethanol, 2-naphthyl-beta-d-galactopyranoside hydride, benzyl mevalonic lactone ester of maleic acid, 3-(4-sulfophenyl)azoacetoacetoxy ethyl methacrylate and its tetrahydroammonium salt, 3-(4-hydroxycarbonylphenyl)azoacetoacetoxy ethyl methacrylate and its tetrahydroammonium salt, N-(3-hydroxy-4-hydroxycarbonylphenylazo)phenyl methacrylamide and its tetrahydroammonium salt, styrene, hydroxystyrene, acetoxystyrene, vinyl benzoate, vinyl 4-tert-butylbenzoate, ethylene glycol phenyl ether acrylate, phenoxypropyl acrylate, 2-(4-benzoyl-3-hydroxyphenoxy)ethyl acrylate, 2-hydroxy-3-phenoxypropyl acrylate, phenyl methacrylate, benzyl methacrylate, 9-anthracenylmethyl methacrylate, 9-vinylanthracene, 2-vinylnaphthalene, N-vinylphthalimide, N-(3-hydroxy)phenyl methacrylamide, N-(3-hydroxy-4-nitrophenylazo)phenyl methacrylamide, N-(3-hydroxyl-4-ethoxycarbonylphenylazo)phenyl methacrylamide, N-(2,4-dinitrophenylaminophenyl)maleimide, 3-(4-acetoaminophenyl)azo-4-hydroxystyrene, 3-(4-ethoxycarbonylphenyl)azo-acetoacetoxy ethyl methacrylate, 3-(4-hydroxyphenyl)azo-acetoacetoxy ethyl methacrylate, 3-(4-nitrophenyl)azoacetoacetoxy ethyl methacrylate, 3-(4-methoxycarbonylphenyl)azoacetoacetoxy ethyl methacrylate.

Examples of the polymer useful for this embodiment are copolymers of acrylic acid, methacrylic acid, vinyl alcohol, maleic anhydride, thiophenes maleic acid, maleimide, N-methyl maleimide, N-vinyl pyrrolidinone or mixtures thereof, with methyl methacrylate, butyl methacrylate, hydroxyethyl methacrylate, hydroxypropyl methacrylate, styrene, hydroxystyrene or mixtures thereof.

Examples of antireflective coating compositions comprise 1) a copolymer of at least one of maleimide, N-methylmaleimide, vinyl alcohol, allyl alcohol, acrylic acid, methacrylic acid, maleic anhydride, thiophene, methacrylate ester of beta-hydroxy-gamma-butyrolactone, 2-methyl-2-adamantyl methacrylate, with at least one of methyl methacrylate, hydroxyethyl methacrylate, 3-hydroxy-1-adamantyl methacrylate, styrene, hyroxystyrene and methcrylate eater of mevalonic lactone, 2) a dye such as triphenylphenol, 9-anthracenemethanol, benzyl mevalonic lactone ester of maleic acid, polymer of benzyl methacrylate, hydroxystyrene, 9-anthracenylmethyl methacrylate, and 3-acetoaminophenylazo-4-hydroxystyrene with methyl methacrylate and hydroxyethyl methacrylate , 3) a crosslinker such as tetrakis(methoxymethyl)glycoluril and hexaalkoxymethylmelamine, 4) a photoacid generator such as triphenylsulfonium nonaflate, diphenyliodonium nonaflate, and 2,1,4-diazonaphthoquinones, optionally, 4) some additives such as amine and surfactant, and 5) solvent or mixtures of solvents such as propylene glycol monomethyl ether acetate, propylene glycol monomethyl ether, and ethyl lactate.

In a third embodiment of the invention a nonphotosensitive antireflective coating composition comprises a crosslinking agent and a polymer with at least one unit which makes the polymer alkali soluble. Polymers disclosed in the specification may be used. There is no photoacid generator in the antireflective coating composition. Heating the bilevel system after the exposure step causes the photogenerated acid from the top negative photoresist to diffuse into the antireflective coating to cause crosslinking in the antireflective coating. In such cases particularly thin coatings of the antireflective coating are preferred. Coatings in the range of 600 to 150 Angstroms may be used.

In a fourth embodiment of the invention the antireflective coating composition comprises a photoactive compound and a polymer that changes polarity or functionality in the presence of the photolyzed photoactive compound such that its solubility in aqueous base is changed from soluble to insoluble after exposure. The absorbance can be intrinsic to the polymer or due to an added dye. The polymer of the fourth embodiment is synthesized from, for example, monomers that change functionality or polarity in the presence of acid, such as monomers containing gamma hydroxy carboxylic acids which lactonize in the presence of acid, such as is described in Yokoyama et al. Proc. SPIE, Vol. 4345, (2001), p. 58-66 and Yokoyama et al. J. of Photopolymer Sci. and Techn. Volume 14, No. 3, p. 393. Another example of such a monomer is a monomer containing a pinacol functionality, such as that described in S. Cho et al., Proc SPIE, Vol. 3999, (2000) pps. 62-73. The change in solubility is not due to a crosslinking mechanism.

Examples of antireflective coating compositions comprise 1) a copolymer of at least one monomer of acetoxystyrene, hydroxystyrene, styrene, benzyl methacrylate, phenyl methacrylate, 9-anthracenylmethyl methacrylate, 9-vinylanthracene, 3-(4-methoxycarbonylphenyl)azoacetoacetoxy ethyl methacrylate, and 3-(4-hodroxycarbonylphenyl)azoacetoacetoxy ethyl methacrylate, with at least one monomer of maleic anhydride or maleimide and 5(2,3-dihydroxy-2,3-dimethyl)butylbicyclo[2.2.1]hept-2-ene, 2) a photoacid generator such as triphenylsulfonium nonaflate, diphenyliodonium nonaflate, optionally, 4) some additives such as amine and surfactant, and 5) solvent or mixtures of solvents such as propylene glycol monomethyl ether acetate, propylene glycol monomethyl ether, and ethyl lactate.

Another example of antireflective coating compositions comprise 1) a copolymer of at least one monomer of acetoxystyrene, hydroxystyrene, styrene, benzyl methacrylate, phenyl methacrylate, 9-anthracenylmethyl methacrylate, 9-vinylanthracene, 3-(4-methoxycarbonylphenyl)azoacetoacetoxy ethyl methacrylate, and 3-(4-hodroxycarbonylphenyl)azoacetoacetoxy ethyl methacrylate, with at least one monomer of maleic anhydride that has been treated with sodium borohydride to reduce the polymer bound anhydride to a gamma hydroxy acid, 2) a photoacid generator such as triphenylsulfonium nonaflate, diphenyliodonium nonaflate, and optionally,3) some additives such as amine and surfactant, and 4) solvent or mixtures of solvents such as propylene glycol monomethyl ether acetate, propylene glycol monomethyl ether, and ethyl lactate.

In a fifth embodiment, the antireflective coating composition consists of a polymer that changes polarity or functionality in the presence of the acid compound such that its solubility in aqueous base is changed from soluble to insoluble after exposure. The polymer is similar to the one described in the fourth embodiment. The absorbance can be intrinsic to the polymer or due to an added dye. There is effectively no photoacid generator in the composition. In this case the change in polarity and functionality in the antireflective coating is caused by the diffusion of the photogenerated acid from the top negative photoresist into the antireflective coating after the exposure step and during the baking step. The change in solubility is not due to a crosslinking mechanism.

Examples of antireflective coating compositions comprise 1) a copolymer of at least one monomer of maleic anydride norbornene that has been treated with sodium borohydride to reduce the polymer bound anhydride to a gamma hydroxy lactone, 2) a dye such as triphenylphenol, 9-anthracenemethanol, benzyl mevalonic lactone ester of maleic acid, polymer of benzyl methacrylate, hydroxystyrene, 9-anthracenylmethyl methacrylate, and 3-acetoaminophenylazo4-hydroxystyrene with methyl methacrylate and hydroxyethyl methacrylate , 3) a photoacid generator such as triphenylsulfonium nonaflate, diphenyliodonium nonaflate, and 2,1,4-diazonaphthoquinones, optionally, 4) some additives such as amine, and 5) solvent or mixtures of solvents such as propylene glycol monomethyl ether acetate, propylene glycol monomethyl ether, and ethyl lactate.

Another example of antireflective coating compositions comprise 1) a copolymer of at least one monomer of maleimide or maleic anydride and 5(2,3-dihydroxy-2,3-dimethyl)butylbicyclo[2.2.1]hept-2-ene, 2) a dye such as triphenylphenol, 9-anthracenemethanol, benzyl mevalonic lactone ester of maleic acid, polymer of benzyl methacrylate, hydroxystyrene, 9-anthracenylmethyl methacrylate, and 3-acetoaminophenylazo4-hydroxystyrene with methyl methacrylate and hydroxyethyl methacrylate, 3) a photoacid generator such as triphenylsulfonium nonaflate, diphenyliodonium nonaflate, and 2,1,4-diazonaphthoquinones, optionally, 4) some additives such as amine, and 5) solvent or mixtures of solvents such as propylene glycol monomethyl ether acetate, propylene glycol monomethyl ether, and ethyl lactate.

The polymers may be synthesized using any known method of polymerization, such as ring-opening metathesis, free-radical polymerization, condensation polymerization, using metal organic catalysts, or anionic or cationic copolymerization techniques. The polymer may be synthesized using solution, emulsion, bulk, suspension polymerization, or the like. The polymers of this invention are polymerized to give a polymer with a weight average molecular weight from about 1,000 to about 1,000,000, preferably from about 2,000 to about 80,000, more preferably from about 4,000 to about 50,000. When the weight average molecular weight is below 1,000, then good film forming properties are not obtained for the antireflective coating and when the weight average molecular weight is too high, then properties such as solubility, storage stability and the like may be compromised. The polydispersity (Mw/Mn) of the free-radical polymers, where Mw is the weight average molecular weight and Mn is the number average molecular weight, can range from 1.5 to 10.0, where the molecular weights of the polymer may be determined by gel permeation chromatography.

The solvent for the antireflective coating is chosen such that it can dissolve all the solid components of the antireflective coating, and also can be removed during the bake step so that the resulting coating is not soluble in the coating solvent of the photoresist. Furthermore, to retain the integrity of the antireflective coating, the polymer of the antireflective coating is also not soluble in the solvent of the top photoresist. Such requirements prevent, or minimize, intermixing of the antireflecting coating layer with the photoresist layer. Typically propylene glycol monomethyl ether acetate and ethyl lactate are the preferred solvents for the top photoresist. Examples of suitable solvents for the antireflective coating composition are cyclohexanone, cyclopentanone, anisole, 2-heptanone, ethyl lactate, propylene glycol monomethyl ether acetate, propylene glycol monomethyl ether, butyl acetate, gamma butyroacetate, ethyl cellosolve acetate, methyl cellosolve acetate, methyl 3-methoxypropionate, ethyl pyruvate, 2-methoxybutyl acetate, 2-methoxyethyl ether, but ethyl lactate, propylene glycol monomethyl ether acetate, propylene glycol monomethyl ether or mixtures thereof are preferred. Solvents with a lower degree of toxicity and good coating and solubility properties are generally preferred.

Typical antireflective coating compositions of the present invention may comprise up to about 15 percent by weight of the solids, preferably less than 8%, based on the total weight of the coating composition. The solids may comprise from 0 to 25 weight percent of the photoacid generator, 40 to 99 weight percent of polymer, 1 to 60 weight percent of the crosslinking agent, and optionally 5 to 95 weight percent of the dye, based on the total solids content of the photoresist composition. The solid components are dissolved in the solvent, or mixtures of solvents, and filtered to remove impurities. The components of the antireflective coating may also be treated by techniques such as passing through an ion exchange column, filtration, and extraction process, to improve the quality of the product.

Other components may be added to enhance the performance of the coating, e.g. lower alcohols, surface leveling agents, adhesion promoters, antifoaming agents, etc. These additives may be present at 0 to 20 weight percent level. Other polymers, such as, novolaks, polyhydroxystyrene, polymethylmethacrylate and polyarylates, may be added to the composition, providing the performance is not negatively impacted. Preferably the amount of this polymer is kept below 50 weight % of the total solids of the composition, more preferably 20 weight %, and even more preferably below 10 weight %.

The absorption parameter (k) of the novel composition ranges from about 0.1 to about 1.0, preferably from about 0.15 to about 0.7 as measured using ellipsometry. The refractive index (n) of the antireflective coating is also optimized. The exact values of the optimum ranges for k and n are dependent on the exposure wavelength used and the type of application. Typically for 193 nm the preferred range for k is 0.2 to 0.75, for 248 nm the preferred range for k is 0.25 to 0.8, and for 365 nm the preferred range is from 0.2 to 0.8. The thickness of the antireflective coating is less than the thickness of the top photoresist. Preferably the film thickness of the antireflective coating is less than the value of (wavelength of exposure/refractive index), and more preferably it is less than the value of (wavelength of exposure/2 times refractive index), where the refractive index is that of the antireflective coating and can be measured with an ellipsometer. The optimum film thickness of the antireflective coating is determined by the exposure wavelength, substrate, refractive indices of the antireflective coating and of the photoresist, and absorption characteristics of the top and bottom coatings. Since the bottom antireflective coating must be removed by exposure and development steps, the optimum film thickness is determined by avoiding the optical nodes or standing wave where no light absorption is present in the antireflective coating. For 193 nm a film thickness of less than 55 nm is preferred, for 248 nm a film thickness of less than 80 nm is preferred and for 365 nm a film thickness of less than 110 nm is preferred.

The antireflective coating composition is coated on the substrate using techniques well known to those skilled in the art, such as dipping, spin coating or spraying. The preferred range of temperature is from about 40° C. to about 240° C., preferably from about 70° C. to about 160° C. The film thickness of the antireflective coating ranges from about 20 nm to about 200 nm. The optimum film thickness is determined, as is well known in the art, to be where no standing waves are observed in the photoresist. It has been unexpectedly found that for this novel composition very thin coatings can be used due to the excellent absorption and refractive index properties of the film. The coating is further heated on a hot plate or convection oven for a sufficient length of time to remove any residual solvent, and thus insolubilizing the antireflective coating to prevent intermixing between the antireflective coating and the photoresist layer. The antireflective coating is also soluble at this stage in the alkaline developing solution.

Negative photoresists, which are developed with aqueous alkaline solutions, are useful for the present invention, provided the photoactive compounds in the photoresist and the antireflective coating absorb at the same exposure wavelength used for the imaging process of the photoresist. Negative-working photoresist compositions are exposed image-wise to radiation, those areas of the photoresist composition exposed to the radiation become more insoluble in the developer solution (e.g. a crosslinking reaction occurs) while those areas not exposed remain soluble in the developer solution. Thus, treatment of an exposed negative-working photoresist with the developer causes removal of the unexposed areas of the coating and the formation of a negative image in the photoresist coating. Photoresist resolution is defined as the smallest feature, which the photoresist composition can transfer from the photomask to the substrate with a high degree of image edge acuity after exposure and development. In many manufacturing applications today, photoresist resolution on the order of less than one micron are necessary. In addition, it is almost always desirable that the developed photoresist wall profiles be near vertical relative to the substrate. Such demarcations between developed and undeveloped areas of the resist coating translate into accurate pattern transfer of the mask image onto the substrate. This becomes even more critical as the drive toward miniaturization reduces the critical dimensions on the devices.

Negative-acting photoresists comprising novolak resins or polyhydroxystyrene, a crosslinking agent and quinone-diazide compounds as photoactive compounds are well known in the art. Novolak resins are typically produced by condensing formaldehyde and one or more multi-substituted phenols, in the presence of an acid catalyst, such as oxalic acid. Photoactive compounds are generally obtained by reacting multihydroxyphenolic compounds with naphthoquinone diazide acids or their derivatives. Oxime sulfonates have also been described as photoacid generators for negative photoresists as disclosed in U.S. Pat. No. 5,928,837, and incorporated by reference. The sensitivity of these types of resists typically ranges from about 300 nm to 440 nm.

Photoresists sensitive to short wavelengths, between about 180 nm and about 300 nm can also be used. These photoresists normally comprise polyhydroxystyrene or substituted polyhydroxystyrene derivatives, a crosslinking agent, a photoactive compound, and optionally a solubility inhibitor. The following references exemplify the types of photoresists used and are incorporated herein by reference, Proc. SPIE, vols. 3333 (1998), 3678 (1999), 3999 (2000), 4345 (2001). Particularly preferred for 193 nm and 157 nm exposure are photoresists comprising non-aromatic polymers, a photoacid generator, optionally a solubility inhibitor, and solvent. Photoresists sensitive at 193 nm that are known in the prior art are described in the following references and incorporated herein, Proc. SPIE, vols. 3999 (2000), 4345 (2001), although any photoresist sensitive at 193 nm may be used on top of the antireflective composition of this invention. One such negative photoresist comprises an alkali soluble fluorinated polymer, a photoactive compound and a crosslinking agent. The polymer has at least one unit of structure 1,

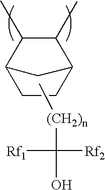

Where, Rf₁ and Rf₂ are independently a perfluorinated or partially fluorinated alkyl group; and n is 1-8. The negative photoresist composition comprises poly[5-(2-trifluoromethyl-1,1,1-trifluoro-2-hydroxypropyl)-2-norbornene], tetramethoxyglycoluril, triphenylsulfonium triflate and propyleneglycolmonomethyl ether acetate.

A film of photoresist is then coated on top of the antireflective coating and baked to substantially remove the photoresist solvent. The photoresist and the antireflective coating bilevel system is then imagewise exposed. In a subsequent heating step the acid generated during exposure reacts to crosslink the polymer and thus render it alkali insoluble in the developing solution. In the unexposed regions the photoresist and the antireflective coating are soluble in the developing solution. The heating step may range in temperature from 110° C. to 170° C., preferably from 120° C. to 150° C. The bilevel system is then developed in an aqueous developer to remove the unexposed photoresist and the antireflective coating. The developer is preferably an aqueous alkaline solution comprising, for example, tetramethyl ammonium hydroxide. The developer may further comprise additives, such as surfactants, polymers, isopropanol, ethanol, etc. The process of coating and imaging photoresist coatings and antireflective coatings is well known to those skilled in the art and is optimized for the specific type of photoresist and antireflective coating combination used. The imaged bilevel system can then be processed further as required by the manufacturing process of integrated circuits, for example metal deposition and etching.

Each of the documents referred to above are incorporated herein by reference in its entirety, for all purposes. The following specific examples will provide detailed illustrations of the methods of producing and utilizing compositions of the present invention. These examples are not intended, however, to limit or restrict the scope of the invention in any way and should not be construed as providing conditions, parameters or values which must be utilized exclusively in order to practice the present invention.

### EXAMPLES

### Synthetic Example 1

In a 250 ml round bottom flask was placed 9.10 g (0.0812 moles) N-methyl maleimide, 6.6 g (0.041 moles) acetoxystyrene, 4.3 g ( 0.042 moles) styrene, 0.4 g azoisobutylnitrile and 50 g tetrahydrofuran. The reaction was degassed for 10 minutes and the reaction heated to reflux with stirring for 5 hours. The reaction was next added to 600 ml hexane with stirring. The precipitated poly styrene-acetoxystyrene-N-methylmaleimide was dried at 50° C. under vacuum.

Five grams of the above polymer were added to 10 g of 40% aqueous N-methylamine and 20 g of N-methyl pyrolididone. The mixture was heated in a 100 ml round bottom flask with a condenser and stirred at 70° C. for 3 hours. Next the reaction was added to 600 ml of 5% aqueous hydrochloric acid with stirring. The slurry was filtered and washed well with deionized (DI) water. The polymer was dried at 50° C. under vacuum. The weight average molecular weight of this polymer, as measured by gas permeation chromatography, was 48,200. The polymer coating gave a refractive index and absorption at 193 nm for n and k of 1.599 and 0.644 respectively as measured by a J. A. Woollam WVASE 32™ Ellipsometer.

### Synthetic Example 2

In a 250 ml round bottom flask is placed 9.10 g (0.0812 moles) N-methyl maleimide, 6.6 g (0.041 moles) acetoxystyrene, 4.3 g (0.042 moles) methacrylic ester of 9-anthracenemethanol (AMMA), 0.4 g azoisobutylnitrile and 60 g tetrahydrofuran. The reaction is degassed and the reaction heated to reflux with stirring for 5 hours. The reaction is next added to 600 ml hexane with stirring. The precipitated poly AMMA-acetoxystyrene-N-methylmaleimide is dried at 50° C. under vacuum.

Five grams of the above polymer is added to 10 g of 40% aqueous N-methylamine and 20 grams of N-methyl pyrolididone. The mixture is heated in a 100 ml round bottom flask with a condenser and stirring at 70° C. for 3 hours. Next the reaction is added to 600 ml of 5% aqueous hydrochloric acid with stirring. The slurry is filtered and washed well with DI water. The polymer is dried at 50° C. under vacuum.

### Formulation Example 1

In 99.98 g of diacetone alcohol was dissolved 1.27 g of the polymer from Synthetic Example 1, 0.22 g of Cymel 303 (a product of CYTEC Corp., West Paterson, N.J.), 0.01 g of FC-4430 (fluoroaliphatic polymeric ester, supplied by 3M Corporation, St. Paul Minn.) and 0.09g of CGI 1325 photoacid generator (a product of Ciba Corp., Basel, Switzerland). The bottom antireflective coating formulation was filtered through a 0.2 micron filter.

### Formulation Example 2

In 99.98 g of diacetone alcohol is dissolved 1.27 g of the polymer from Synthetic Example 2, 0.22 g of Cymel 303, 0.01 g of FC-4430 (fluoroaliphatic polymeric ester, supplied by 3M Corporation, St. Paul Minn.)and 0.09 g of CGI 1325 photoacid generator. The bottom antireflective coating formulation is filtered through a 0.2 micron filter.

### Formulation Example 3

Two Solutions Were Prepared as Follows:

Solution 1: In 121.197 g of ethyl lactate was added to 2.052 g of polymer from Synthetic Example 1, and 0.113 g of 10% Megafac R08 (available from Diappon Ink and Chem, Mikawa, Japan) in propylene glycol monomethyl ether acetate (PGMEA).

Solution 2: In 119.038 g of ethyl lactate was dissolved 2.527 g of poly(hydroxystyrene-methacrylate), 3-(azo-4-acetanilide) and 1.048 g of Powderlink N2702 (a product of CYTEC Corp., West Paterson, N.J.).

A solution was made by taking 120 g of “solution 1” and 79 g of “solution 2”. To this solution was added, 0.6 g of 50.86% Cymel 303 (a product of CYTEC Corp., West Paterson, N.J.) in PGMEA, and 18.011 g of a 1.726 % solution of CGI 1325 in diacetone alcohol. The bottom antireflective coating formulation was filtered through a 0.2 micron filter.

### Formulation Example 4

To 20.055 g of a 0.901% solution of polymer from Synthetic Example 1 in diacetone alcohol was added 0.068 g of 50% Cymel 303 in PGMEA. This solution was filtered through a 0.2 micron filter.

### Formulation Example 5

0.988 g of poly[5-(2-trifluoromethyl-1,1,1-trifluoro-2-hydroxypropyl)-2-norbornene] (Mw 8,300, Mn/Mw=1.69), 0.247 g of tetramethoxyglycoluril, 0.013 g of triphenylsulfonium triflate, 0.122 g of 1 wt % propyleneglycol monomethylether acetate (PGMEA) solution of tetrabutylammonium hydroxide and 0.012 g of 10 wt % PGMEA solution of a surfactant FC 4430 (fluoroaliphatic polymeric ester, supplied by 3M Corporation, St. Paul Minn.) were dissolved in 8.62 g of PGMEA to give a photoresist solution. The solution was filtered using 0.2 μm filter.

### Lithographic Example 1

The bottom antireflective coating solution from Formulation Example 1 was coated on HMDS primed 6″ silicon wafer to 300 Angstroms of uniform coating. The bottom antireflective coating was soft baked at 90° C. for 60 seconds to obtain a dry polymer film. The negative photoresist from formulation example 5 was coated on top of the wafer with bottom antireflective coating to give a 3,300 Angstroms thick photoresist layer and soft baked at 90° C. for 60 seconds. The coated wafer was then exposed on a 193 nm ISI ministepper (numerical aperture of 0.6 and coherence of 0.7) using a chrome on quartz binary mask. The binary mask has a pattern of lines and spaces. After exposure, the wafer was post-exposure baked at 150° C. for 60 sec. Immediately after post exposure bake (PEB), the wafer was developed for 60 seconds with an aqueous developer, AZ 300 MIF (available from Clariant Corporation, Somerville, N.J.), rinsed with DI water for 15 seconds and spun dried. The resulting structures were examined by scanning electron microscopy, and the images showed no intermixing and 0.4 μm dense lines were resolved without standing waves.

### Lithographic Example 2

An 8 inch HMDS primed silicon wafer was coated with 557 Å of the bottom antireflective coating solution from Formulation Example 1. A soft bake of 90° C. for 90 seconds was used. On this coated wafer was formed a coating of 3063 Å of negative photoresist as prepared in Formulation Example 5. The wafer was soft baked at 90° C. for 90 seconds. The double coated wafer was exposed on a 248 nm DUV stepper from 8 to 48 mJ/cm². A post exposure bake of 110° C./90 sec was used. The wafer was next developed using a single 60 second puddle of AZ 300 MIF. Clean images were obtained without any intermixing.

### Lithographic Example 3

The antireflective coating from Formulation Example 1 was coated on HMDS primed 6″ silicon wafer to give 300 Angstroms of uniform coating. The coating was soft baked at 90° C. for 60 seconds. The negative i-line photoresist AZ® N6010 (a product available from Clariant Corporation, Somerville, N.J.) was coated on top of the antireflective coating to produce a 1.0 um thick photoresist layer and baked at 90° C. for 60 seconds. The coated wafer was exposed with a line and space pattern using a 365 nm step and repeat exposure tool. A post exposure bake of 110° C./90 sec was used. Immediately after the PEB, the wafer was developed for 60 second with AZ 300 MIF, rinsed with DI water for 15 seconds and spun dried. The resulting structures were examined by scanning electron microscopy, which showed that the images were cleanly formed for dense 1 μm lines.

### Lithographic Example 4

The bottom antireflective coating from Formulation Example 3 was coated on a HMDS primed 6″ silicon wafer to coat 600 Angstroms of uniform coating. The bottom antireflective coating was soft baked at 90° C. for 60 seconds. The negative i-line photoresist AZ® NLOF 5510 (a product of Clariant Corporation) was coated on top of the applied antireflective coating to produce a 0.986 um thick photoresist layer and soft baked at 90° C. for 60 seconds. The coated wafer was exposed with a line and space pattern mask using a 365 nm step and repeat exposure tool. A post exposure bake of 110° C./60 sec was used. Immediately after the PEB, the wafer was developed for 120 second with AZ 300 MIF Developer, rinsed with DI water for 15 seconds and spun dried. The resulting structures were cleanly formed.

### Lithographic Example 5

The bottom antireflective coating from Formulation Example 4 was coated on HMDS primed 6″ silicon wafer to give 300 Angstroms of uniform coating. The bottom antireflective coating was soft baked at 90° C. for 60 seconds. The negative i-line photoresist AZ® NLOF 5510 (a product of AZ Corporation) was coated on top of the applied bottom antireflective coating to produce a 0.79 um thick photoresist layer and soft baked at 90° C. for 60 seconds. The coated wafer was exposed with a line and space pattern mask using a 365 nm step and repeat exposure tool. A post exposure bake of 110° C./60 sec was used. Immediately after the PEB, the wafer was developed for 120 seconds with an aqueous developer, AZ 300 MIF Developer, rinsed with DI water for 15 seconds and spun dried. The resulting structures were cleanly formed for dense 0.7 μm lines. This is an example of acid migration from the photoresist to cross link the bottom layer.

1. The composition of claim 23, further comprising a crosslinking agent.

2. The composition according to claim 23, further comprising a dye.

3. The composition according to claim 2, where the dye is selected from a monomeric dye, a polymeric dye and a mixture of a monomeric and a polymeric dyes.

4. A composition according to claim 2, where the dye is selected from compounds containing substituted and unsubstituted phenyl, substituted and unsubstituted anthracyl, substituted and unsubstituted phenanthryl, substituted and unsubstituted naphthyl, substituted and unsubstituted heterocyclic aromatic rings containing heteroatoms selected from oxygen, nitrogen, sulfur, or combinations thereof.

5. The composition according to claim 23, where the polymer further comprises at least one unit with an absorbing chromophore.

6 The composition according to claim 5, where the chromophore is selected from compounds containing hydrocarbon aromatic rings, substituted and unsubstituted phenyl, substituted and unsubstituted anthracyl, substituted and unsubstituted phenanthryl, substituted and unsubstituted naphthyl, substituted and unsubstituted heterocyclic aromatic rings containing heteroatoms selected from oxygen, nitrogen, sulfur, or combinations thereof.

7. A composition according to claim 1 where the polymer is selected from a copolymer of at least one of acetoxystyrene, hydroxystyrene, styrene, benzyl methacrylate, phenyl methacrylate, 9-anthracenylmethyl methacrylate, 9-vinylanthracene, 3-(4-methoxycarbonylphenyl)azoacetoacetoxy ethyl methacrylate, and 3-(4-hydroxycarbonylphenyl)azoacetoacetoxy ethyl methacrylate, with at least one of maleimide, N-methyl maleimide, N-alkynol maleimide, vinyl alcohol, allyl alcohol, acrylic acid, methacrylic acid, maleic anhydride, thiophene, methacrylate ester of beta-hydroxy-gamma-butyrolactone, 2-methyl-2-adamantyl methacrylate, 3-hydroxy-1-adamantyl methacrylate, and methacrylate ester of mevalonic lactone.

8. A composition according to claim 23 where the antireflective layer has a k value in the range of 0.1 to 1.0.

9. (canceled)

10. The composition according to claim 23, where the antireflective coating is substantially insoluble in a solvent of the top photoresist.

11-21. (canceled)

22. (canceled)

23. A negative bottom photoimageable antireflective coating composition which is capable of being developed in an aqueous alkaline developer and which is coated below a negative photoresist, where the antireflective coating composition comprises an aqueous alkali soluble polymer that becomes insoluble in an aqueous alkaline developer after exposure, further where the antireflective coating composition is capable of forming an antireflective layer below a Photoresist layer with a maximum coating thickness of λ/2n, where λ is wavelength of exposure and n is refractive index of the antireflective coating composition, and a minimum coating thickness greater than zero.

24. (canceled)

25. The composition according to claim 1, further comprising a photoacid generator.

26. The composition according to claim 25, where the polymer further comprises at least one unit with an absorbing chromophore.

27. The composition according to claim 26, where the chromophore is selected from compounds containing hydrocarbon aromatic rings, substituted and unsubstituted phenyl, substituted and unsubstituted anthracyl, substituted and unsubstituted phenanthryl, substituted and unsubstituted naphthyl, substituted and unsubstituted heterocyclic aromatic rings containing heteroatoms selected from oxygen, nitrogen, sulfur, or combinations thereof.

31. The composition according to claim 25 where the polymer is selected from a copolymer of at least one of acetoxystyrene, hydroxystyrene, styrene, benzyl methacrylate, phenyl methacrylate, 9-anthracenylmethyl methacrylate, 9-vinylanthracene, 3-(4-methoxycarbonylphenyl)azoacetoacetoxy ethyl methacrylate, and 3-(4-hydroxycarbonylphenyl)azoacetoacetoxy ethyl methacrylate, with at least one of maleimide, N-methyl maleimide, N-alkynol maleimide, vinyl alcohol, allyl alcohol, acrylic acid, methacrylic acid, maleic anhydride, thiophene, methacrylate ester of beta-hydroxy-gamma-butyrolactone, 2-methyl-2-adamantyl methacrylate, 3-hydroxy-1-adamantyl methacrylate, and methacrylate ester of mevalonic lactone.

28. The composition according to claim 25, further comprising a dye.

29. The composition of 23, where the polymer changes polarity.

30. The composition of claim 23, where the polymer is synthesized from at least one monomer selected from a group comprising hydroxy carboxylic acid and pinacol.

31. The composition of claim 23, further comprising a photoacid generator.

32. The composition of claim 23, where the antireflective layer is capable of forming a latent image.

33. The composition of claim 1, where the crosslinking agent is selected from melamines, methylols, glycolurils, hydroxyl alkyl amides, epoxy and epoxy amine resins, blocked isocyanates, and divinyl monomers.

34. The composition of claim 25, where the photoacid generator is selected from onium salts, sulfonate esters of hyroxyimides, substituted or unsubstituted naphthalimidyl triflate or sulsfonates and diazonaphthoquinones.

35. The composition of claim 31, where the photoacid generator is selected from onium salts, sulfonate esters of hyroxyimides, substituted or unsubstituted naphthalimidyl triflate or sulsfonates and diazonaphthoquinones.
